(19) United States
(12) Patent Application Publication
(10) Pub. No.: US 2015/0066401 A1
(43) Pub. Date: Mar. 5, 2015

(54) State Estimation of Power Systems Decomposed Into Two or More Subsystems

(71) Applicant: ABB Technology AG, Zurich (CH)

(72) Inventors: Vaibhav D. Donde, Cary, NC (US); Xiaoming Feng, Cary, NC (US)

(21) Appl. No.: 14/017,448

(22) Filed: Sep. 4, 2013

(51) Int. Cl. G01R 21/133

(52) U.S. Cl. CPC G01R 21/133
USPC 702/60

(57) ABSTRACT

A power system grid is decomposed into several parts and decomposed state estimation steps are executed separately, using Lagrangian relaxation and blockwise Gauss-Seidel solution. The achieved solution is the same that would be achieved with a simultaneous state estimation approach. With the disclosed approach, the state estimation problem can be distributed among decomposed estimation operations for each subsystem, where the decomposed estimation operations coordinate with one another to yield the complete state estimate. The approach is particularly suited for estimating the state of power systems that are naturally decomposed into separate subsystems, such as separate AC and HVDC systems, and/or separate transmission and distribution systems.

### TECHNICAL FIELD

The present disclosure relates to state estimation of an electrical power grid, and more particularly relates to an approach facilitating the coordinated state estimation of decomposed portions of a power grid.

### BACKGROUND

Power system state estimation is an important prerequisite function for the intelligent management of a power grid. Two types of state estimator (SE), namely, static and dynamic are possible for realization. Traditionally, static state estimation techniques are used by the electric power industry to estimate the state (typically the magnitudes and angles of the bus voltage phasors) of power transmission and distribution systems, due to the techniques' relative simplicity and the ready availability of supervisory control and data acquisition (SCADA) data that is often obtained at relatively slow sampling rates. Dynamic state estimation, on the other hand, would allow power system operators to observe and respond to transient state changes in the power system, and is likely to become more relevant with the increasing availability of fast-sampled sensor data, such as phasor measurement unit (PMU) data.

State estimation is typically executed on the entire power grid, under the jurisdiction of the governing and/or monitoring entity, e.g., an independent system operator (ISO) or utility, while considering all the components and their interactions in the grid at once. However, several changes in the power industry are resulting in systems where a single governing and/or monitoring entity may no longer have immediate access to measurements across the entire grid. For instance, in some cases operational control of transmission grids is performed by an entity other than the generating/distributing utilities. These changes, coupled with the rapidly increasing complexity of power systems, create challenges for power system state estimation. Accordingly, improved techniques for power system state estimation are needed.

### SUMMARY

According to several embodiments of the techniques detailed herein, a power system grid is decomposed into several parts and decomposed state estimation steps are executed separately and iteratively, on each part. The achieved solution is the same that would be achieved with a simultaneous state estimation approach. However, with this approach, the state estimation problem can be distributed among decomposed estimation operations for each subsystem that coordinate with one another to yield the complete state estimate. The approach is particularly suited for estimating the state of power systems that are naturally decomposed into separate subsystems, such as separate AC and HVDC systems, and/or into separate transmission and distribution systems.

An example method according to the disclosed techniques is for state estimation in a power system that comprises a first subsystem and a second subsystem having corresponding first and second state vectors and having one or more common boundary buses, the first state vector comprising m state variables, including k state variables for the common boundary buses, and the second state vector comprising n state variables, including the k state variables for the common boundary buses. The method begins with forming a first group of m equations that represent first order optimality conditions for a weighted-least-squares (WLS) optimization problem and that relate the first state vector to internal measurements for the first subsystem and a Lagrangian multiplier, based on an application of Lagrangian relaxation to the WLS optimization problem for solving for the first and second state vectors based on corresponding first and second measurement vectors and corresponding first and second subsystem measurement transfer functions relating the respective first and second state vectors to the respective first and second state vectors. In addition, a second group of n equations are formed, the second group of equations representing first order optimality conditions for the WLS optimization problem and relating the second state vector to internal measurements for the second subsystem and to the Lagrangian multiplier, as well as a third group of k equations that enforce a constraint that the boundary bus states included in each of the first and second state vectors are equal to one another.

Next, the first, second, and third groups of equations for the first and second state vectors are solved, using a blockwise Gauss-Seidel approach, such that the estimations of the first and second state vectors in each iteration of the Gauss-Seidel solution are decoupled from one another. In some embodiments, the solving of the first, second, and third groups of equations for the first and second state vectors is performed according to an iterative approach, as follows: a current estimate for the second state vector and the Lagrangian multiplier are initialized; the first group of equations is solved to obtain a current estimate of the first state vector, based on the current estimates for the second state vector and the Lagrangian multiplier; the second and third groups of equations are solved simultaneously to obtain revised current estimates for the second state vector and the Lagrangian multipler, based on the current estimate of the first state vector; and the solving of the first group of equations and the solving of the second and third groups of equations are repeated until a convergence criterion is satisfied.

In some embodiments, the solving of the first group of equations is performed in a first processor and the solving of the second and third group of equations is performed in a second processor, distinct from the first processor. In some of these embodiments, for each iteration the current estimate for the boundary bus states from the first state vector is passed from the first processor to the second processor, after solving the first group of equations, and the current estimates for the boundary states from the second state vector and the Lagrangian multiplier are passed from the second processor to the first processor, after solving the second and third groups of equations.

In some embodiments, the first subsystem corresponds to one or more AC grids in the power system and the second subsystem corresponds to one or more DC grids in the power system. In other embodiments, the first subsystem comprises a transmission portion of an electrical power grid and the second subsystem comprises a distribution portion of the electrical power grid.

Some embodiments further incorporate bus injection measurements at the boundary buses into the state estimation problem. Accordingly, in some embodiments the first group of equations further relates the first state vector to bus injection measurements at the boundary buses in the first subsystem and the second group of equations further relates the second state vector to bus injection measurements at the boundary buses in the second subsystem. In some of these embodiments, the solving of the first group of equations is performed in a first processor and the solving of the second and third group of equations is performed in a second processor, distinct from the first processor. In these embodiments, after solving the first group of equations for each iteration, boundary bus injection pseudo-measurements for the second subsystem are calculated, based on the current estimate of the first state vector, and the boundary bus injection pseudo-measurements for the second subsystem and a current estimate for at least the state of the common boundary buses are passed from the first processor to the second processor. Likewise, after solving the second and third group of equations for each iteration, boundary bus injection pseudo-measurements for the first subsystem are calculated, based on the current estimate of the second state vector, and the boundary bus injection pseudo-measurements for the first subsystem and the current estimate for the Lagrangian multiplier are passed from the second processor to the first processor.

It will be appreciated that the subsystem state estimation operations may be carried out at distinct nodes, and are independent of one another except for sharing certain current estimates. Thus, other embodiments of the invention include state estimation systems for use in estimating the state of a power system that comprises a first subsystem and a second subsystem having corresponding first and second state vectors and having one or more common boundary buses, the first state vector comprising m state variables, including k state variables for the common boundary buses, and the second state vector comprising n state variables, including the k state variables for the common boundary buses. An example state estimation system comprises at least one processing circuit configured to, based on an application of Lagrangian relaxation to a weighted-least squares (WLs) optimization problem for solving for the first and second state vectors based on corresponding first and second measurement vectors and corresponding first and second subsystem measurement transfer functions relating the respective first and second state vectors to the respective first and second state vectors, form a first group of m equations that represent first order optimality conditions for the WLS optimization problem and that relate the first state vector to internal measurements for the first subsystem and a Lagrangian multiplier, form a second group of n equations that represent first order optimality conditions for the weighted-least squares optimization problem and that relate the second state vector to internal measurements for the second subsystem and to the Lagrangian multiplier, and form a third group of k equations that enforce a constraint that the boundary bus states included in each of the first and second state vectors are equal to one another. The at least one processing circuit is further configured to solve the first, second, and third groups of equations for the first and second state vectors, using a blockwise Gauss-Seidel approach, such that the estimations of the first and second state vectors in each iteration of the Gauss-Seidel solution are decoupled from one another. The example state estimation system further comprises at least one memory configured to store the estimates of the first and second state vectors and the Lagrangian multiplier.

Each of the variations of method summarized above and detailed in the following description are equally applicable to the state estimation system embodiments. Thus, some embodiments of the state estimation system comprise two subsystem processors configured to carry out one or more of the state estimation techniques described herein in a decomposed fashion, coordinating with one another through the exchange of certain current estimates. Those skilled in the art will recognize variations of the above-summarized embodiments, as well as additional features and advantages of the disclosed techniques, upon reading the following detailed description and upon viewing the accompanying drawings.

### BRIEF DESCRIPTION OF THE DRAWINGS

The components in the figures are not necessarily to scale, emphasis instead being placed upon illustrating the principles of the invention. Moreover, in the figures, like reference numerals designate corresponding parts. In the drawings:

FIG. 1 illustrates an example power system before decomposition;

FIG. 2 illustrates the same power system after partitioning into first and second subsystems, with a shared boundary;

FIGS. 3 and 4 illustrate the separated subsystems;

FIG. 5 is a process flow diagram illustrating details of a Gauss-Siedel solution of state estimation problems corresponding to the separated subsystems of FIGS. 3 and 4;

FIG. 6 illustrates schematically the solution of the decomposed state estimation problem;

FIG. 7 is a process flow diagram illustrating a generalized method for power system state estimation according to the inventive techniques disclosed herein; and

FIG. 8 illustrates an example processing circuit.

### DETAILED DESCRIPTION

Described herein are techniques for power system state estimation whereby a power system is decomposed into several parts on which the state estimation is executed separately, in a coordinated way, such that the solution obtained is the same as that from the simultaneous solution. The techniques employ a general formulation of the state estimation problem that is applicable to solving the state estimation problem for a power grid.

It will be appreciated that one specific application of the disclosed techniques is given by the growing integration of HVDC grids into power grids worldwide. These systems can be naturally decomposed the system into AC and HVDC subsystems. Using the disclosed techniques, state estimates for each of the AC and HVDC systems can be obtained in a distributed, coordinated fashion. However, the techniques are not limited in their application to AC/HVDC systems. For instance, the disclosed techniques may also be applied to power systems that can be decomposed into one or more transmission subsystems and one or more distribution subsystems. More generally, the techniques may be applied to many different subdivisions of a power system, provided only that the state of each subsystem is over-determined by the measurements available for that subsystem, given the state of any boundaries between the subsystem and the one or more other subsystems being analyzed.

Traditionally, state estimation is executed on an entire system as a whole. In many cases, it is of interest to execute it separately on parts of the system, e.g., for administrative reasons. It is important that the process of state estimation through system decomposition is carefully designed such that it minimizes the mismatch at the boundaries of the system parts, obtains the solution in reasonable numerical efforts and time. The disclosed techniques achieve these requirements. The systems and processes disclosed herein are intended for use in the energy management system (EMS) of electrical power systems where the overall system is an interconnection of multiple subsystems, such as in the case of hybrid AC-DC grid systems where the DC grid is a meshed DC network connecting multiple converter stations.

According to several embodiments of the present invention, then, the state estimation problem for interconnected system is solved through a decomposition approach, such that:
the system is decomposed into multiple smaller subsystems, or sub-networks, the subystems sharing a set of boundary buses;
a modified state estimation problem is solved separately for each subsystem, such that the states related to the boundary buses are uniquely defined, using estimates of the boundary bus measurements, boundary bus states and an adjustment vector (Lagrangian multiplier vector) obtained from other parts; and
the state estimation steps are iterated until convergence.

The solution obtained by this method is the same as that from a simultaneous solution of the entire system. The disclosed techniques employ a general formulation that is applicable to solve a state estimation problem for a power grid. A specific application is provided by the growing integration of HVDC grids into power grids worldwide which naturally decomposes the system into AC and HVDC subsystems. Using the disclosed method, AC and HVDC systems can each obtain state estimates in a coordinated fashion. However the techniques are not limited to AC/HVDC systems.

For convenience and clarity, the following discussion describes the application of the present techniques to a power system divided into two subsystems, without any loss of generality. It will be readily appreciated by those knowledgeable in the field of state estimation that the techniques can be extended to power systems divided into three or more subsystems.

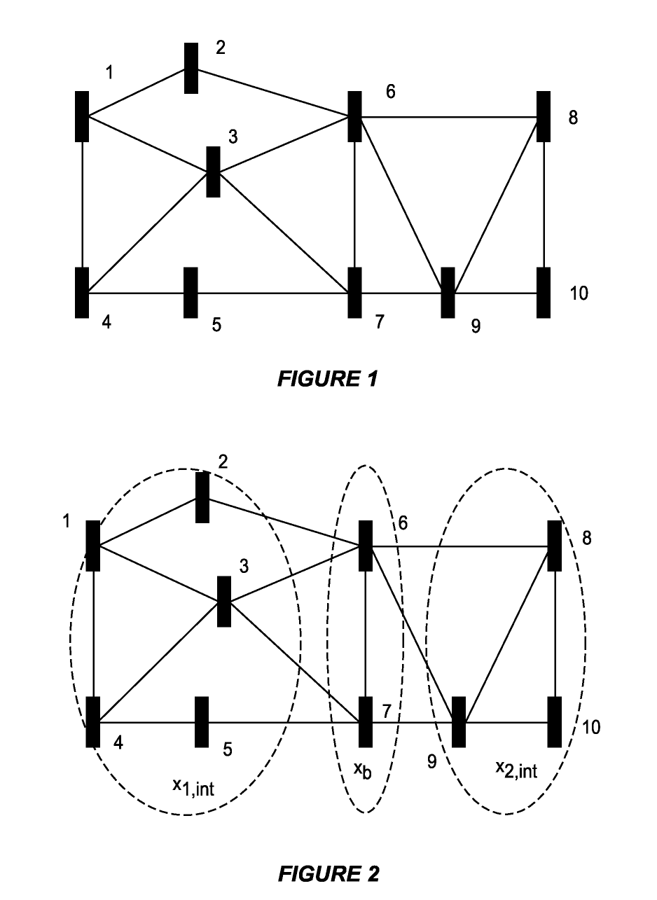

FIG. 1 is a simplified illustration of an example power system having ten interconnected, numbered nodes. For the purposes of the following detailed discussion, this should be understood as the entire power system of interest, although it will be understood that this is a simplified example and that the techniques described herein are extensible to much more extensive and complicated systems.

In general terms, the objective of state estimation is to determine the state vector that minimizes a defined distance metric between a vector of system measurements, i.e., a measurement vector, and a measurement function vector evaluated at the estimated state vector. Given a vector of measurements z, a state vector x, and a system response function h(x) that relates the measurements to the state vector, i.e., according to z=h(x), then the common weighted-least-square (WLS) state estimation problem is thus defined as

$${{Min}_{x} ( z - h ( \hat{x} ) )}^{T} W ( z - h ( \hat{x} ) ) ,$$

where \hat{x} is an estimate of the state vector x and W is a weighting matrix. More particularly:

W⁻¹=R

where R is the covariance matrix of the measurement errors associated with measurement vector z. Commonly, R is constrained to be a diagonal matrix of the individual measurement variances, i.e.,

R=diag[σ₁²σ₂²σ₃² . . . σₘ²],

where m is the number of measurements in z.

In a power system, the state vector x commonly can be represented as

x=(V,δ),

where V is a vector of bus voltage phasor magnitudes and δ is a corresponding vector of bus voltage phasor angles. However, it will be appreciated that the state vector may comprise other state variables, as well.

Common measurements that make up the measurement vector z include nodal measurements, such as bus voltage, phase angle, real and reactive power injections, etc. Other common measurements include branch measurements, such as branch power flow, current magnitude, and the like.

The first-order optimality condition of the WLS state estimation problem is:

H^{T}(\hat{x})W(z−h(\hat{x}))=0,

where

$${H}^{T} ( \hat{x} ) = \frac{\partial h ( \hat{x} )}{\partial \hat{x}}$$

is the Jacobian matrix of the measurement functions with respect to the state variables, evaluated at the state estimate \hat{x}.

The optimality condition is commonly solved iteratively with the following iteration equations:

\hat{x}^{k+1}=\hat{x}^{k}+Δ\hat{x}^{k},

and

(H^{T}(\hat{x}^{k})WH(\hat{x}^{k}))Δ\hat{x}^{k}=H^{T}(\hat{x}^{k})W(z−h(\hat{x}^{k})).

FIGS. 2, 3, and 4 illustrate the partitioning of the system shown in FIG. 1 into two subsystems, having a shared boundary. First, as shown at FIG. 2, boundary nodes 6 and 7, having a state vector x_{b}, are isolated from the rest of the system, leaving a first group of nodes 1-5, having a state vector x_{1,int}, and a second group of nodes 8-10, having a state vector x_{2,int}. The two subsystems have a shared boundary, which in the illustrated example includes nodes 6 and 7 and which has a state vector x_{b}. Typically:

x_{1,int}=(V₁,δ₁);

x_{2,int}=(V₂,δ₂);

and

x_{b}=(V_{b},δ_{b})

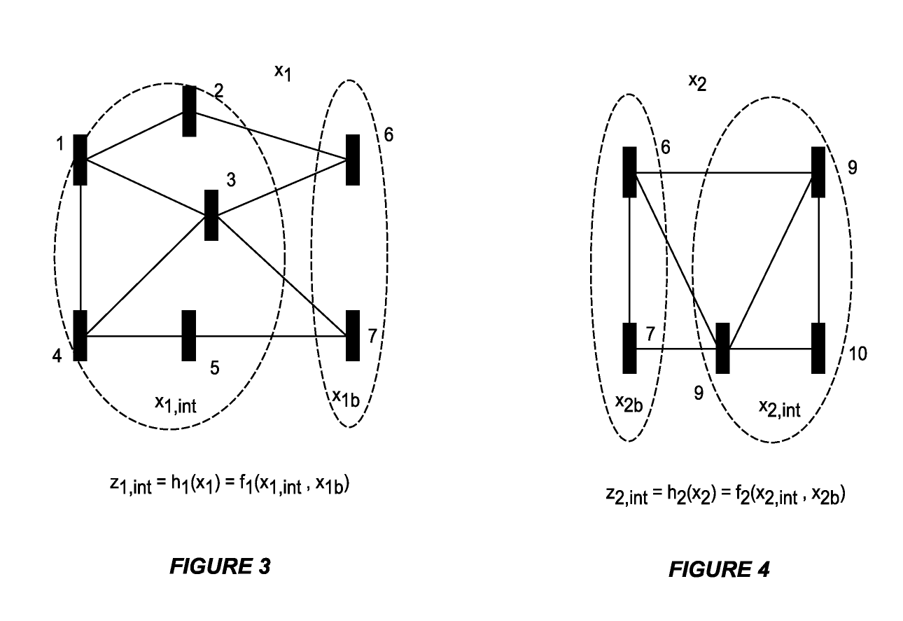

Next, two completely separate subsystems are shown in FIGS. 3 and 4. Here, the entire system is divided into multiple parts such that the buses on the boundary are duplicated. The boundary bus states are x_{1b} and x_{2b}, and corresponding measurement vectors z_{b}′ and z_{b}″ respectively. The first subsystem, shown in FIG. 3, includes nodes 1-5 and boundary nodes 6 and 7, and has a state vector x₁, which includes state vector x_{1,int}, representing the state of nodes 1-5, and boundary bus state vector x_{1b}. The second subsystem includes nodes 8, 9, and 10, and has a state vector x₂, which includes state vector x_{2,int}, representing the state of nodes 8-10, and boundary bus state vector x_{2b}. Similarly, the measurements are divided into three groups, as shown in FIGS. 3, and 4, where z_{1,int} is the interior measurement vector of the first subsystem, z_{2,int} is the interior measurements vector for the second subsystem, and z_{b}′ and z_{b}″ are the boundary bus measurement vectors for the first and second subsystems, respectively. Likewise, each subsystem has a corresponding measurement function vector. Thus, h₁(x₁) is the interior measurement function vector of the first subsystem and h₂(x₂) is the interior measurement function vector of the second subsystem.

Summing up variables and their relationships to the subsystems pictured in FIGS. 3 and 4:

x_{1,int}=states internal to subsystem 1;

x₁=entire state vector of subsystem 1 (including boundary bus states);

z_{1,int}=measurements internal to subsystem 1. They are related to the entire subsystem 1 as z_{1,int}=h₁(x₁);

x_{2,int}=states internal to subsystem 2;

x₂=entire state vector of subsystem 2 (including boundary bus states); and

z_{2,int}=measurements internal to subsystem 2. They are related to the entire subsystem 2 as z_{2,int}=h₂(x₂).

As seen in FIG. 3, the measurement vector z_{1,int} for the first subsystem is a function of the state vectors x_{1,int} and x_{1b}. Likewise, as seen in FIG. 4, the measurement vector z_{2,int} for the second subsystem is a function of the state vectors x_{2,int} and x_{2b}. This suggests that the state of each subsystem can be evaluated separately, given that the solutions are coordinated so as to agree on solutions for x_{1b} and x_{2b}. As will be seen, this can be done with an iterative approach.

A mathematical justification for this approach begins with a recognition that the internal states of the subsystems are related to their entire states by the following relations:

$${x}_{1} = [ \begin{matrix}{x}_{1 , int} \\ {x}_{1 b}\end{matrix} ] ⇒ {x}_{1 b} = \underbrace{[ 0 I ]}_{{K}_{1}} {x}_{1}$$

$${x}_{2} = [ \begin{matrix}{x}_{2 , int} \\ {x}_{2 b}\end{matrix} ] ⇒ {x}_{2 b} = \underbrace{[ 0 I ]}_{{K}_{2}} {x}_{2}$$

Thus:

$$\frac{\partial {h}_{1} ( {x}_{1} )}{\partial {x}_{2 b}} = 0 , \\ \frac{\partial {h}_{2} ( {x}_{2} )}{\partial {x}_{1 b}} = 0.$$

The Weighted Least Squares (WLS) optimization problem for the overall system is defined as having the objective function:

$${min}_{{x}_{1} , {x}_{2}} {( {z}_{1 , int} - {h}_{1} ( {x}_{1} ) )}^{T} {W}_{1} ( {z}_{1 , int} - {h}_{1} ( {x}_{1} ) ) + {( {z}_{2 , int} - {h}_{2} ( {x}_{2} ) )}^{T} {W}_{2} ( {z}_{2 , int} - {h}_{2} ( {x}_{2} ) ) ,$$

with the constraint that (x_{1b}−x_{2b})=0.

The equality constraint maintains continuity at the boundary of the sub-systems by enforcing the boundary bus states to be identical. Note that according to the terminology defined above, this equality constraint is equivalent to:

(K₁x₁−K₂x₂)=0.

It is also noted that the boundary measurements z_{b} have been neglected for now; these will be reintroduced later in this discussion.

Applying Lagrangian relaxation to the optimization problem above yields:

$${min}_{{x}_{1} , {x}_{2} , λ} {( {z}_{1 , int} - {h}_{1} ( {x}_{1} ) )}^{T} {W}_{1} ( {z}_{1 , int} - {h}_{1} ( {x}_{1} ) ) + {( {z}_{2 , int} - {h}_{2} ( {x}_{2} ) )}^{T} {W}_{2} ( {z}_{2 , int} - {h}_{2} ( {x}_{2} ) ) + {λ}^{T} ( {K}_{1} {x}_{1} - {K}_{2} {x}_{2} ) . \qquad ( 1 )$$

The first order optimality conditions are given by:

−H₁(x₁)^{T}W₁(x_{1,int}−h₁(x₁))+K₁^{T}λ=0 (2)

−H₂(x₂)^{T}W₂(z_{2,int}−h₂(x₂))−K₂^{T}λ=0 (3)

(K₁x₁−K₂x₂)=0 (4)

Solution without Boundary Measurements

Given that X₁ε [symbol] ^{m}, x₂ε [symbol] ⁿ, x_{1b}ε [symbol] ^{k}, x_{2b}ε [symbol] ^{k}, we have m equations in expression (2) above, n equations in expression (3) and k equations in expression (4). This “square” system of equations can be solved simultaneously, or by Gauss-Seidel method in order to decouple state-estimation-like solutions of each subsystem.

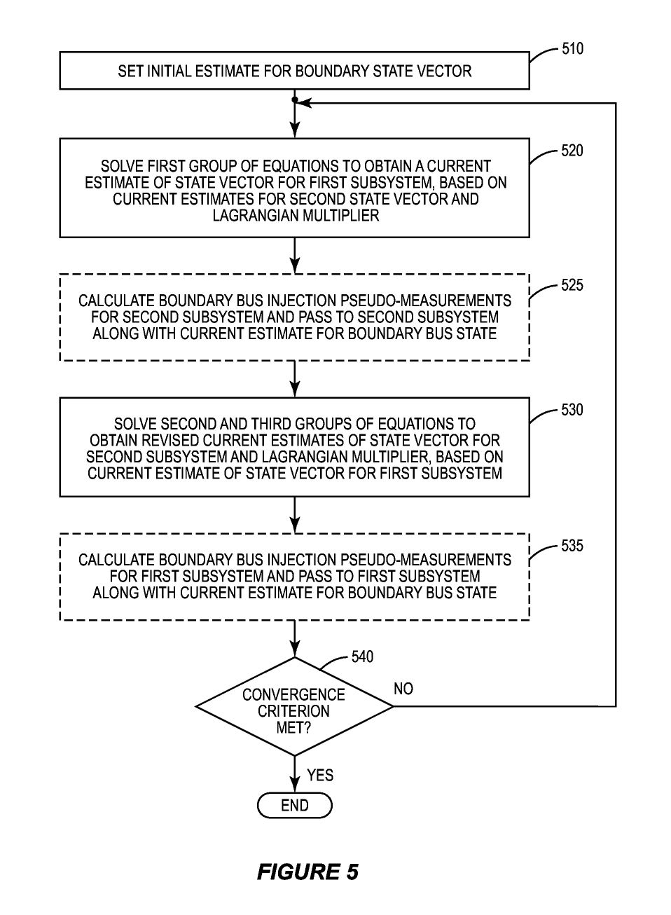

Using the Gauss-Seidel approach results in a decoupling between equation (2) and (3)-(4), and results in the following algorithm, which is illustrated in FIG. 5:

Step 1: Initialize x₁, x₂ and λ to obtain current values of each. This is shown at block 510 of FIG. 5. The initialized values can be arbitrary, but may be set to values obtained from an earlier solution, in some embodiments.

Step 2: Assuming the current values of x₂ and from the initialization step or from a previous iteration, solve (2) to obtain a new current value of x₁. This is shown at block 520 of FIG. 5. The set of equations we need to solve is given by (2), that is:

H₁(x₁)^{T}W₁(z_{1,int}−h₁(x₁))−K₁^{T}λ=0.

This is a system of nonlinear equations in x₁. For an infinitesimally small variation Δx₁ in x₁, it can be rewritten in the form:

H₁(x₁)^{T}W₁(z_{1,int}−h₁(x₁)−H₁(x₁)Δx₁)−K₁^{T}λ=0

[symbol]

(H₁^{T}W₁H₁)Δx₁=H₁(x₁)^{T}W₁(z_{1,int}−h₁(x₁))−K₁^{T}λ.

In other words, the updated value of x₁ is obtained by solving the following modified state estimation problem:
Do until converged
   Solve: (H₁^{T}W₁H₁)Δx₁=H₁(x₁)^{T}W₁(x_{1,int}−h₁(x₁))−K₁^{T}λ
   x₁=x₁+Δx₁
End
   Note that this has a form of the normal equation, modified by the adjustment vector −K₁^{T}λ.

Step 3: Assume x₁ as obtained by the last step and solve expressions (3) and (4) simultaneously to obtain new current values for x₂ and λ. This is shown at block 530 of FIG. 5. As was the case with step 2, this step also involves a solution of a set of nonlinear equations. The equations to be solved are given by expressions (3) and (4) which are equivalent to:

H₂(x₂)^{T}W₂(z_{2,int}−h₂(x₂))+K₂^{T}=0

(K₁x₁−K₂x₂)=0.

The updated values of x₂ and λ can be obtained by solving the following modified state estimation problem:

$$Do until converged$$

$$Solve \text{:} [ \begin{matrix}{H}_{2}^{T} {W}_{2} {H}_{2} & - {K}_{2}^{T} \\ - {K}_{2} & 0\end{matrix} ] [ \begin{matrix}Δ {x}_{2} \\ Δλ\end{matrix} ] = [ \begin{matrix}{{H}_{2} ( {x}_{2} )}^{T} {W}_{2} ( {z}_{2 , int} - {h}_{2} ( {x}_{2} ) ) + {K}_{2}^{T} λ \\ ( {K}_{2} {x}_{2} - {K}_{1} {x}_{1} )\end{matrix} ]$$

$${x}_{2} = {x}_{2} + Δ {x}_{2}$$

$$λ = λ + Δλ$$

$$End$$

Note again that this has a form of the normal equation, in this case augmented by the boundary state continuity constraint. The right-hand side (RHS) of the augmented normal equation is modified by the adjustment vector +K₂^{T}λ.

Step 4: Check convergence of the overall solution. This is shown at block 540 of FIG. 5. If the solution has converged to within a predetermined convergence criterion, then the algorithm is complete. If not, steps 2-4 are repeated.

It will be observed that the system of equations (2)-(4) is broken asymmetrically, i.e., into (2) and (3)-(4). This asymmetry is intentional. If expression (2) is assumed to represent a modified state estimation of an AC grid, then the solution of this equation would require only a minimal modification to any existing AC grid state estimation solution (e.g., only the right-hand side vector modification). In this case, equations (3)-(4) can represent a modified augmented DC grid state estimation problem that can be formulated and solved on the DC grid side. Since a DC grid state estimation solution would typically have to be built as a new system, the more extensive differences between this solution and a conventional approach are less disruptive to existing systems.

Solution Incorporating Boundary Bus Injection Measurements

In the formulation presented in the last section, boundary bus injection measurements were neglected. They did not appear in the objective function or the equality constraint. If an original (simultaneous) problem also neglected the boundary bus injection measurements then the solution found by the Gauss-Seidel method as outlined above will coincide with the original (simultaneous) solution due to the enforcement of the boundary state equivalence in the objective function. However, if boundary bus injections were incorporated in an original simultaneous solution, the results of the preceding technique will yield a different solution.

To overcome this limitation, the technique is reformulated here, with incorporation of the boundary bus injection measurements. The overall objective function defined in the previous section is modified to include the boundary bus injection measurements:

$${min}_{{x}_{1} , {x}_{2}} {( {z}_{1 , int} - {h}_{1} ( {x}_{1} ) )}^{T} {W}_{1} ( {z}_{1 , int} - {h}_{1} ( {x}_{1} ) ) + {( {z}_{2 , int} - {h}_{2} ( {x}_{2} ) )}^{T} {W}_{2} ( {z}_{2 , int} - {h}_{2} ( {x}_{2} ) ) + {( {z}_{b} - {h}_{b} ( {x}_{1} , {x}_{2} ) )}^{T} {W}_{b} ( {z}_{b} - {h}_{b} ( {x}_{1} , {x}_{2} ) ) , \\ subject to the constraint that ( {K}_{1} {x}_{1} - {K}_{2} {x}_{2} ) = 0. \qquad ( 5 )$$

Then, the Lagrangian relaxation based optimization problem is modified:

$${min}_{{x}_{1} , {x}_{2} , λ} {( {z}_{1 , int} - {h}_{1} ( {x}_{1} ) )}^{T} {W}_{1} ( {z}_{1 , int} - {h}_{1} ( {x}_{1} ) ) + {( {z}_{2 , int} - {h}_{2} ( {x}_{2} ) )}^{T} {W}_{2} ( {z}_{2 , int} - {h}_{2} ( {x}_{2} ) ) + {( {z}_{b} - {h}_{b} ( {x}_{1} , {x}_{2} ) )}^{T} {W}_{b} ( {z}_{b} - {h}_{b} ( {x}_{1} , {x}_{2} ) ) + {λ}^{T} ( {K}_{1} {x}_{1} - {K}_{2} {x}_{2} ) .$$

The first order optimality conditions are given by:

$$\begin{matrix}- {{H}_{1} ( {x}_{1} )}^{T} {W}_{1} ( {z}_{1 , int} - {h}_{1} ( {x}_{1} ) ) + {K}_{1}^{T} λ - {{H}_{b}^{′} ( {x}_{1} )}^{T} {W}_{b} ( \underbrace{{z}_{b} - {h}_{b}^{″} ( {x}_{2} )}_{{z}_{{b}^{′}}} - {h}_{b}^{′} ( {x}_{1} ) ) = 0 & ( 6 ) \\ - {{H}_{2} ( {x}_{2} )}^{T} {W}_{2} ( {z}_{2 , int} - {h}_{2} ( {x}_{2} ) ) - {K}_{2}^{T} λ - {{H}_{b}^{″} ( {x}_{2} )}^{T} {W}_{b} ( \underbrace{{z}_{b} - {h}_{b}^{′} ( {x}_{1} )}_{{z}_{{b}^{″}}} - {h}_{b}^{″} ( {x}_{2} ) ) = 0 & ( 7 ) \\ ( {K}_{1} {x}_{1} - {K}_{2} {x}_{2} ) = 0. \\ Here , \\ {h}_{b} ( {x}_{1} , {x}_{2} ) is rearranged as {h}_{b} ( {x}_{1} , {x}_{2} ) = {h}_{b}^{′} ( {x}_{1} ) + {h}_{b}^{″} ( {x}_{2} ) , \\ and {H}_{b}^{′} ( {x}_{1} ) = \frac{\partial {h}_{b}^{′} ( {x}_{1} )}{\partial {x}_{1}} , {H}_{b}^{″} ( {x}_{2} ) = \frac{\partial {h}_{b}^{″} ( {x}_{2} )}{\partial {x}_{2}} . & ( 8 )\end{matrix}$$

Equations (6)-(8) can be solved in the same manner given above for equations (2)-(4). That is, the Gauss-Seidel approach is used, resulting in a decoupling between equation (6) and equations (7)-(8). This results in the following algorithm, which again is illustrated in FIG. 5:

Step 1: Initialize x₁, x₂ and λ to obtain current values of each. Again, this is shown at block 510 of FIG. 5. The initialized values can be arbitrary, but may be set to values obtained from an earlier solution, in some embodiments.

Step 2: Assuming the current values of x₂ and λ from the initialization step or from a previous iteration, solve the nonlinear equation (6) to obtain a new current value of x₁. This is shown at block 520 of FIG. 5. In this case, the step update is obtained as:

$$( [ {H}_{1}^{T} {H}_{b}^{′T} ] [ \begin{matrix}{W}_{1} & \\ & {W}_{b}\end{matrix} ] [ \begin{matrix}{H}_{1} \\ {H}_{b}^{′}\end{matrix} ] ) Δ {x}_{1} = [ {H}_{1}^{T} {H}_{b}^{′T} ] [ \begin{matrix}{W}_{1} & \\ & {W}_{b}\end{matrix} ] [ \begin{matrix}{z}_{1 , int} - {h}_{1} ( {x}_{1} ) \\ {z}_{b}^{′} - {h}_{b}^{′} ( {x}_{1} )\end{matrix} ] - {K}_{1}^{T} λ . \\ This can be further simplified to \text{:} \\ ( \underbrace{[ {H}_{1}^{T} {H}_{b}^{′T} ] [ \begin{matrix}{W}_{1} & \\ & {W}_{b}\end{matrix} ] [ \begin{matrix}{H}_{1} \\ {H}_{b}^{′}\end{matrix} ]}_{Original Gain Matrix of the AC grid \\ with pseudo \text{-} measurements} ) Δ {x}_{1} = \underbrace{[ {H}_{1}^{T} {H}_{b}^{′T} ] [ \begin{matrix}{W}_{1} & \\ & {W}_{b}\end{matrix} ] [ \begin{matrix}{z}_{1 , int} - {h}_{1} ( {x}_{1} ) \\ {z}_{b}^{′} - {h}_{b}^{′} ( {x}_{1} )\end{matrix} ]}_{Original RHS of the AC grid \\ with pseudo \text{-} measurements} - [ \begin{matrix}0 \\ λ\end{matrix} ] \qquad ( 9 )$$

Step 3: Solve equations (7)-(8) simultaneously, by using the new current value of x₁ to obtain x₂ and λ. This is shown at block 530 in FIG. 5. The step updates Δx₂ and Δλ are obtained as:

$$[ \begin{matrix}( [ {H}_{2}^{T} {H}_{b}^{″T} ] [ \begin{matrix}{W}_{2} & \\ & {W}_{b}\end{matrix} ] [ \begin{matrix}{H}_{1} \\ {H}_{b}^{″}\end{matrix} ] ) & - {K}_{2}^{T} \\ - {K}_{2} & 0\end{matrix} ] [ \begin{matrix}Δ {x}_{2} \\ Δ λ\end{matrix} ] = [ \begin{matrix}[ {H}_{2}^{T} {H}_{b}^{″T} ] [ \begin{matrix}{W}_{2} & \\ & {W}_{b}\end{matrix} ] [ \begin{matrix}{z}_{2 , int} - {h}_{2} ( {x}_{2} ) \\ {z}_{b}^{″} - {h}_{b}^{″} ( {x}_{2} )\end{matrix} ] + {K}_{2}^{T} λ \\ - ( {K}_{1} {x}_{1} - {K}_{2} {x}_{2} )\end{matrix} ] . \\ This can be further simplified to \text{:} \\ [ \begin{matrix}( \underbrace{[ {H}_{2}^{T} {H}_{b}^{″T} ] [ \begin{matrix}{W}_{2} & \\ & {W}_{b}\end{matrix} ] [ \begin{matrix}{H}_{1} \\ {H}_{b}^{″}\end{matrix} ]}_{Original Gain matrix of the DC grid \\ with pseudo \text{-} measurements} ) & [ \begin{matrix}0 \\ - I\end{matrix} ] \\ [ 0 - I ] & 0\end{matrix} ] [ \begin{matrix}Δ {x}_{2} \\ Δ λ\end{matrix} ] = [ \begin{matrix}\underbrace{[ {H}_{2}^{T} {H}_{b}^{″T} ] [ \begin{matrix}{W}_{2} & \\ & {W}_{b}\end{matrix} ] [ \begin{matrix}{z}_{2 , int} - {h}_{2} ( {x}_{2} ) \\ {z}_{b}^{″} - {h}_{b}^{″} ( {x}_{2} )\end{matrix} ] + [ \begin{matrix}0 \\ λ\end{matrix} ]}_{Original RHS of the DC grid \\ with pseudo \text{-} measurements} \\ ( {x}_{2 b} - {x}_{1 b} )\end{matrix} ] . \qquad ( Equation ( 10 ) )$$

Note that equations (9) and (10) have structural similarities. In (10), the augmented Gain matrix is symmetric.

Step 4: Check convergence and repeat steps 2-4 if not converged. This is shown at block 540 in FIG. 5.

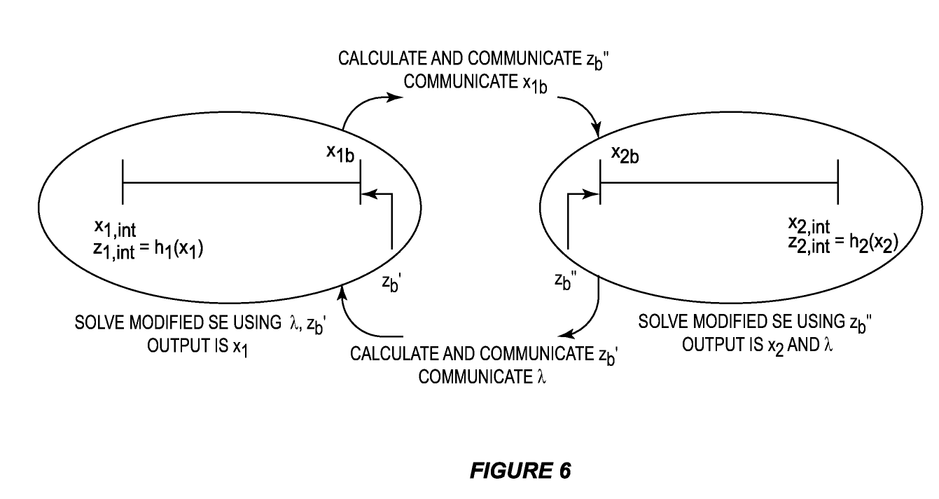

It should be noted that when any of the techniques shown in FIG. 5 and described above is implemented separately, e.g., at separate computing platforms within the respective subsystems, then variables need to be exchanged between the computing platforms at each iteration. First, the boundary bus injection pseudo-measurements and the boundary bus states are communicated from the first subsystem to the second subsystem. This is conveniently done by first calculating the boundary bus injection pseudo-measurements z_{b}″ for the second subsystem and passing the calculated pseudo-measurements z_{b}″ and a current estimate x_{1b} for the boundary buses to the second subsystem. This is shown at block 525 of FIG. 5, which is outlined with a dashed line to indicate that it is “optional” in the sense that it need not appear in every instance or in every implementation of the illustrated techniques. The boundary bus states x_{1b} that are estimated by the first subsystem are used in the right-hand side of equation (10), which is solved by the platform associated with the second subsystem. In addition, the current estimate for the Lagrange multiplier λ and the boundary bus injection pseudo-measurements z_{b}′ for the first subsystem need to be communicated from the second subsystem to the first subsystem. This is shown at block 535 of FIG. 5, which also is illustrated as “optional.” This communication between the two subsystems is illustrated in FIG. 6, which illustrates the entire iterative process.

The techniques illustrated in FIGS. 5 and 6 and detailed above are readily mapped to several different approaches for decomposing a power system into subsystems. In one example, the first subsystem in a two-subsystem decomposition is an AC portion of a hybrid AC-DC grid system, while the second subsystem is a HVDC portion of the hybrid AC-DC grid system. In another example, the first subsystem in a two-subsystem decomposition is a transmission portion of an electrical power grid and the second subsystem is a distribution portion of the electrical power grid. It will be appreciated that a power system may be decomposed into more than two subsystems, and the techniques described above extended to a multi-part solution of the state estimation problem.

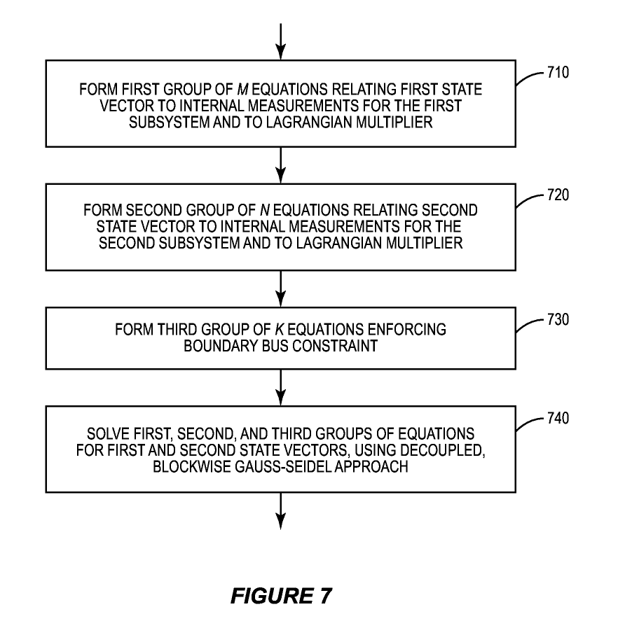

With the above detailed explanations in mind, it will be appreciated that FIG. 7 illustrates a generalized method for state estimation according to the above-described techniques, for a power system that includes a first subsystem and a second subsystem having corresponding first and second state vectors and having one or more common boundary buses, the first state vector comprising m state variables, including k state variables for the common boundary buses, and the second state vector comprising n state variables, including the k state variables for the common boundary buses. Note that the illustrated method may be applied to systems that comprise more than two subsystems.

The method begins, as shown at block 710, with forming a first group of m equations representing first order optimality conditions and relating the first state vector to internal measurements for the first subsystem and a Lagrangian multiplier. This is done based on an application of Lagrangian relaxation to a weighted-least squares optimization problem for solving for the first and second state vectors based on corresponding first and second measurement vectors and corresponding first and second subsystem measurement transfer functions relating the respective first and second state vectors to the respective first and second measurement vectors.

Next, as shown at block 720, a second group of n equations are formed, this second group of equations representing first order optimality conditions for the weighted-least squares optimization problem and relating the second state vector to internal measurements for the second subsystem and to the Lagrangian multiplier. As shown at block 730, a third group of k equations are formed, this third group of equations enforcing a constraint that the boundary bus states included in each of the first and second state vectors are equal to one another

Finally, as shown at block 740, the first, second, and third groups of equations are solved to obtain estimates of the first and second state vectors, using a blockwise Gauss-Seidel approach, such that the estimations of the first and second state vectors in each iteration of the Gauss-Seidel solution are decoupled from one another. It will be appreciated that this solving of the first, second, and third groups of equations may be carried out using the detailed techniques explained above and illustrated in FIG. 5, and variants thereof. Thus, in some embodiments, this solution comprises: initializing a current estimate for the second state vector and the Lagrangian multiplier (block 510 of FIG. 5); solving the first group of equations to obtain a current estimate of the first state vector, based on the current estimates for the second state vector and the Lagrangian multiplier (block 520 of FIG. 5); solving the second and third groups of equations simultaneously to obtain revised current estimates for the second state vector and the Lagrangian multipler, based on the current estimate of the first state vector (block 530 of FIG. 5); and repeating said solving of the first group equations and said solving of the second and third groups of equations until a convergence criterion is satisfied.

In some embodiments, the solving of the first group of equations is performed in a first processor and the solving of the second and third group of equations is performed in a second processor, distinct from the first processor. In some of these embodiments, the method further comprises, for each iteration: passing the current estimate for the first state vector from the first processor to the second processor, after solving the first group of equations; and passing the current estimates for the second state vector and the Lagrangian multiplier from the second processor to the first processor, after solving the second and third groups of equations.

In some embodiments, the first subsystem corresponds to one or more AC grids in the power system and the second subsystem corresponds to one or more DC grids in the power system. In other embodiments, the first subsystem comprises a transmission portion of an electrical power grid and the second subsystem comprises a distribution portion of the electrical power grid.

In some embodiments, the first group of equations further relates the first state vector to bus injection measurements at the boundary buses in the first subsystem and the second group of equations further relates the second state vector to bus injection measurements at the boundary buses in the second subsystem. In some of these embodiments, the solving of the first group of equations is performed in a first processor and said solving of the second and third group of equations is performed in a second processor, distinct from the first processor. In these embodiments, the method may further comprise, for each iteration: after solving the first group of equations, calculating boundary bus injection pseudo-measurements for the second subsystem, based on the current estimate of the first state vector, and passing the boundary bus injection pseudo-measurements for the second subsystem and a current estimate for at least the state of the common boundary buses from the first processor to the second processor; and, after solving the second and third group of equations, calculating boundary bus injection pseudo-measurements for the first subsystem, based on the current estimate of the second state vector, and passing the boundary bus injection pseudo-measurements for the first subsystem and the current estimate for the Lagrangian multiplier from the second processor to the first processor.

As suggested above, the technique illustrated in FIG. 7 may be carried out by one or several processing elements, or nodes. In some instances, these nodes may be operated by different entities, e.g., where one subsystem node is operated by the operator of an AC grid network and the other subsystem node is operated by the operator of a HVDC grid network, to collectively operate a hybrid AC-DC grid system. These subsystem nodes may be configured to exchange appropriate parameters according to the techniques described above.

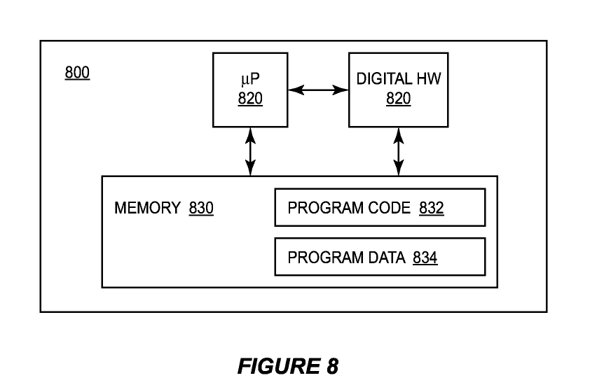

FIG. 8 is a block diagram illustrating an example configuration for a processing circuit 800, which may be present in any one or more of the processing nodes described above. The pictured example includes one or more microprocessors or microcontrollers 810, as well as other digital hardware 820, which may include digital signal processors (DSPs), special-purpose digital logic, and the like. Either or both of microprocessor(s) 810 and digital hardware 820 may be configured to execute program code 832 stored in memory 830 along with program data 834. Again, because the various details and engineering tradeoffs associated with the design of processing circuits are well known and are unnecessary to a full understanding of the invention, additional details are not shown here.

The program code 832 stored in memory circuit 830, which may comprise one or several types of memory such as read-only memory (ROM), random-access memory, cache memory, flash memory devices, optical storage devices, etc., includes program instructions for carrying out all or parts of the power system state estimation techniques described above, in several embodiments. The program data 834 include various pre-determined system configuration parameters, as well as parameters and estimates determined during the state estimation process.

As discussed above, the operations described in FIGS. 5, 6, and 7 can be mapped to one or several processing elements, like processing circuit 800, in any of several different ways. Thus, in some embodiments, one or more processing circuits 800 may form part of a state estimation system for use in estimating the state of a power system that comprises a first subsystem and a second subsystem having corresponding first and second state vectors and having one or more common boundary buses, the first state vector comprising m state variables, including k state variables for the common boundary buses, and the second state vector comprising n state variables, including the k state variables for the common boundary buses. The one or more processing circuits 800 are configured to: based on an application of Lagrangian relaxation to a weighted-least squares optimization problem for solving for the first and second state vectors based on corresponding first and second measurement vectors and corresponding first and second subsystem measurement transfer functions relating the respective first and second state vectors to the respective first and second measurement vectors, form a first group of m equations representing first order optimality conditions and relating the first state vector to internal measurements for the first subsystem and a Lagrangian multiplier; form a second group of n equations representing first order optimality conditions for the weighted-least squares optimization problem and relating the second state vector to internal measurements for the second subsystem and to the Lagrangian multiplier; form a third group of k equations enforcing a constraint that the boundary bus states included in each of the first and second state vectors are equal to one another; and solve the first, second, and third groups of equations for the first and second state vectors, using a blockwise Gauss-Seidel approach, such that the estimations of the first and second state vectors in each iteration of the Gauss-Seidel solution are decoupled from one another. The state estimation system in these embodiments further comprises at least one memory configured to store the estimates of the first and second state vectors and the Lagrangian multiplier.

In some embodiments, the one or more processing circuits 800 are configured to solve the first, second, and third groups of equations for the first and second state vectors by: initializing a current estimate for the second state vector and the Lagrangian multiplier; solving the first group of equations to obtain a current estimate of the first state vector, based on the current estimates for the second state vector and the Lagrangian multiplier; solving the second and third groups of equations simultaneously to obtain revised current estimates for the second state vector and the Lagrangian multipler, based on the current estimate of the first state vector; and repeating said solving of the first group of equations and said solving of the second and third groups of equations until a convergence criterion is satisfied.

In some embodiments, the one or more processing circuits 800 include a first subsystem processor configured to solve the first group of equations and a second subsystem processor, separate from the first subsystem processor, configured to solve the second and third group of equations. In some of these embodiments, the first subsystem processor is configured to pass the current estimate for the first state vector to the second subsystem processor after solving the first group of equations for each iteration, and the second subsystem processor is configured to pass the current estimates for the second state vector and the Lagrangian multiplier to the first subsystem processor, after solving the second and third groups of equations for each iteration. Other variations of the state estimation system are possible, including variants that incorporate bus injection measurements into the solutions of the state estimation problems, as described above.

One key advantage of the techniques and apparatus described above is that they facilitate the separate execution of state estimation for various parts of a power grid system, in a coordinated way. Administrative or practical constraints may require that different parts of the system be addressed separately, while allowing some coordination among them. A leading example is provided by integrated AC and HVDC grid systems.

In the preceding discussion and in the appended claims, terms such as “first”, “second”, and the like, are used to describe various elements, regions, sections, etc. and are not intended to be limiting. Like terms refer to like elements throughout the description. As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method for state estimation in a power system that comprises a first subsystem and a second subsystem having corresponding first and second state vectors and having one or more common boundary buses, the first state vector comprising m state variables, including k state variables for the common boundary buses, and the second state vector comprising n state variables, including the k state variables for the common boundary buses, the method comprising:
based on an application of Lagrangian relaxation to a weighted-least squares (WLS) optimization problem for solving for the first and second state vectors based on corresponding first and second measurement vectors and corresponding first and second subsystem measurement transfer functions relating the respective first and second state vectors to the respective first and second measurement vectors, forming a first group of m equations that represent first order optimality conditions for the WLS optimization problem and that relate the first state vector to internal measurements for the first subsystem and a Lagrangian multiplier;
forming a second group of n equations that represent first order optimality conditions for the WLS optimization problem and that relate the second state vector to internal measurements for the second subsystem and to the Lagrangian multiplier;
forming a third group of k equations that enforce a constraint that the boundary bus states included in each of the first and second state vectors are equal to one another; and
solving the first, second, and third groups of equations for the first and second state vectors, using a blockwise Gauss-Seidel approach, such that the estimations of the first and second state vectors in each iteration of the Gauss-Seidel solution are decoupled from one another.

2. The method of claim 1, wherein solving the first, second, and third groups of equations for the first and second state vectors comprises:
initializing a current estimate for the second state vector and the Lagrangian multiplier;
solving the first group of equations to obtain a current estimate of the first state vector, based on the current estimates for the second state vector and the Lagrangian multiplier;
solving the second and third groups of equations simultaneously to obtain revised current estimates for the second state vector and the Lagrangian multipler, based on the current estimate of the first state vector; and
repeating said solving of the first group of equations and said solving of the second and third groups of equations until a convergence criterion is satisfied.

3. The method of claim 2, wherein said solving of the first group of equations is performed in a first processor and said solving of the second and third group of equations is performed in a second processor, distinct from the first processor, and wherein the method further comprises, for each iteration:
passing the current estimate for the boundary bus states from the first state vector from the first processor to the second processor, after solving the first group of equations; and
passing the current estimates for the boundary bus states from the second state vector and the Lagrangian multiplier from the second processor to the first processor, after solving the second and third groups of equations.

4. The method of claim 1, wherein the first subsystem corresponds to one or more AC grids in the power system and the second subsystem corresponds to one or more DC grids in the power system.

5. The method of claim 1, wherein the first subsystem comprises a transmission portion of an electrical power grid and the second subsystem comprises a distribution portion of the electrical power grid.

6. The method of claim 1, wherein the first group of equations further relates the first state vector to bus injection measurements at the boundary buses in the first subsystem and the second group of equations further relates the second state vector to bus injection measurements at the boundary buses in the second subsystem.

7. The method of claim 6, wherein said solving of the first group of equations is performed in a first processor and said solving of the second and third group of equations is performed in a second processor, distinct from the first processor, and wherein the method further comprises, for each iteration:
after solving the first group of equations, calculating boundary bus injection pseudo-measurements for the second subsystem, based on the current estimate of the first state vector, and passing the boundary bus injection pseudo-measurements for the second subsystem and a current estimate for at least the state of the common boundary buses from the first processor to the second processor; and
after solving the second and third group of equations, calculating boundary bus injection pseudo-measurements for the first subsystem, based on the current estimate of the second state vector, and passing the boundary bus injection pseudo-measurements for the first subsystem and the current estimate for the Lagrangian multiplier from the second processor to the first processor.

8. A state estimation system for use in estimating the state of a power system that comprises a first subsystem and a second subsystem having corresponding first and second state vectors and having one or more common boundary buses, the first state vector comprising m state variables, including k state variables for the common boundary buses, and the second state vector comprising n state variables, including the k state variables for the common boundary buses, the state estimation system comprising
at least one processing circuit configured to:
based on an application of Lagrangian relaxation to a weighted-least squares (WLS) optimization problem for solving for the first and second state vectors based on corresponding first and second measurement vectors and corresponding first and second subsystem measurement transfer functions relating the respective first and second state vectors to the respective first and second measurement vectors, forming a first group of m equations that represent first order optimality conditions for the WLS optimization problem and that relate the first state vector to internal measurements for the first subsystem and a Lagrangian multiplier;
forming a second group of n equations that represent first order optimality conditions for the WLS optimization problem and that relate the second state vector to internal measurements for the second subsystem and to the Lagrangian multiplier;
forming a third group of k equations that enforce a constraint that the boundary bus states included in each of the first and second state vectors are equal to one another; and
solving the first, second, and third groups of equations for the first and second state vectors, using a blockwise Gauss-Seidel approach, such that the estimations of the first and second state vectors in each iteration of the Gauss-Seidel solution are decoupled from one another; and
at least one memory configured to store the estimates of the first and second state vectors and the Lagrangian multiplier.

9. The state estimation system of claim 8, wherein the at least one processing circuit is configured to solve the first, second, and third groups of equations for the first and second state vectors by:
initializing a current estimate for the second state vector and the Lagrangian multiplier;
solving the first group of equations to obtain a current estimate of the first state vector, based on the current estimates for the second state vector and the Lagrangian multiplier;
solving the second and third groups of equations simultaneously to obtain revised current estimates for the second state vector and the Lagrangian multipler, based on the current estimate of the first state vector; and
repeating said solving of the first group of equations and said solving of the second and third groups of equations until a convergence criterion is satisfied.

10. The state estimation system of claim 9, wherein the at least one processing circuit comprises a first subsystem processor configured to solve the first group of equations and a second subsystem processor, separate from the first subsystem processor, configured to solve the second and third group of equations, and wherein:
the first subsystem processor is configured to pass the current estimate for the boundary bus states from the first state vector to the second subsystem processor after solving the first group of equations for each iteration; and
the second subsystem processor is configured to pass the current estimates for the boundary bus states from the second state vector and the Lagrangian multiplier to the first subsystem processor, after solving the second and third groups of equations for each iteration.

11. The state estimation system of claim 8, wherein the first subsystem corresponds to one or more AC grids in the power system and the second subsystem corresponds to one or more DC grids in the power system.

12. The state estimation system of claim 8, wherein the first subsystem comprises a transmission portion of an electrical power grid and the second subsystem comprises a distribution portion of the electrical power grid.

13. The state estimation system of claim 8, wherein the first group of equations further relates the first state vector to bus injection measurements at the boundary buses in the first subsystem and the second group of equations further relates the second state vector to bus injection measurements at the boundary buses in the second subsystem.

14. The state estimation system of claim 13, wherein the at least one processing circuit comprises a first subsystem processor configured to solve the first group of equations and a second subsystem processor, separate from the first subsystem processor, configured to solve the second and third group of equations, and wherein:
the first subsystem processor is further configured to, after solving the first group of equations for each iteration, calculate boundary bus injection pseudo-measurements for the second subsystem, based on the current estimate of the first state vector, and pass the boundary bus injection pseudo-measurements for the second subsystem and a current estimate for at least the state of the common boundary buses to the second subsystem processor; and
the second subsystem processor is further configured to, after solving the second and third group of equations, calculate boundary bus injection pseudo-measurements for the first subsystem, based on the current estimate of the second state vector, and pass the boundary bus injection pseudo-measurements for the first subsystem and the current estimate for the Lagrangian multiplier to the first subsystem processor.
